(19) United States
(12) Patent Application Publication
(10) Pub. No.: US 2006/0238078 A1
(43) Pub. Date: Oct. 26, 2006

(54) Wireless and passive acoustic wave rotation rate sensor

(75) Inventor: James ZT Liu, Belvidere, IL (US)

Correspondence Address: Kris T. Fredrick;Attorney, Intellectual Property, Honeywell International, Inc., 101 Columbia Rd., P.O. Box 2245, Morristown, NJ, 07962, US

(73) Assignee: Honeywell International, Inc.

(21) Appl. No.: 11/112,116

(22) Filed: Apr. 21, 2005

(51) Int. Cl. H01L 41/00

(52) U.S. Cl. 310/338

(57) ABSTRACT

A rotation rate sensing apparatus is configured from an acoustic wave device comprising a plurality of interdigital transducers for the SAW configuration or electrodes for vibration beams configuration. Such sensors are configured upon an elastic substrate. In the SAW configuration, the plurality of interdigital transducers includes a first interdigital transducer, a second interdigital transducer and a third interdigital transducer. A generator(s) can be formed from the first and third interdigital transducers, wherein the generator generates a standing wave subject to a Coriolis force by adding two progressive waves at each of the first and third interdigital transducers. In the vibration beams configuration, a drive beam(s) and pickup beam(s) can be implemented such that the vibration beams are excited through an RF signal and a Coriolis force excites the pickup beam(s) in order to obtain angular/rotation rate data.

### TECHNICAL FIELD

Embodiments are generally related to sensing devices and components thereof, particularly sensor for the detection of rotation rate or gyro data. Embodiments additionally relate to acoustic wave components and devices thereof. Embodiments additionally relate to the wireless transmission of detection data.

### BACKGROUND OF THE INVENTION

Acoustic wave sensors are utilized in a variety of sensing applications, such as, for example, temperature and/or pressure sensing devices and systems. Acoustic wave devices have been in commercial use for over sixty years. Although the telecommunications industry is the largest user of acoustic wave devices, they are also used for sensor applications, such as in chemical vapor detection. Acoustic wave sensors are so named because they use a mechanical, or acoustic wave as the sensing mechanism. As the acoustic wave propagates through or on the surface of the material, any changes to the characteristics of the propagation path affect the velocity and/or amplitude of the wave.

Changes in acoustic wave characteristics can be monitored by measuring the frequency or phase characteristics of the sensor and can then be correlated to the corresponding physical quantity or chemical quantity that is being measured. Virtually all acoustic wave devices and sensors utilize a piezoelectric crystal to generate the acoustic wave. Three mechanisms can contribute to acoustic wave sensor response, i.e., mass-loading, visco-elastic and acousto-electric effect. The mass-loading of chemicals alters the frequency, amplitude, and phase and Q value of such sensors. Most acoustic wave chemical detection sensors, for example, rely on the mass sensitivity of the sensor in conjunction with a chemically selective coating that absorbs the vapors of interest resulting in an increased mass loading of the acoustic wave sensor.

Examples of acoustic wave sensors include acoustic wave detection devices, which are utilized to detect the presence of substances, such as chemicals, or environmental conditions such as temperature and pressure. An acoustical or acoustic wave (e.g., tuning fork, SAW, or BAW) device acting as a sensor can provide a highly sensitive detection mechanism due to the high sensitivity to surface loading and the low noise, which results from their intrinsic high Q factor. Surface acoustic wave devices are typically fabricated using photolithographic techniques with comb-like interdigital transducers placed on a piezoelectric material. Surface acoustic wave devices may have either a delay line, a filter or a resonator configuration. Bulk acoustic wave device are typically fabricated using a vacuum plater, such as those made by CHA, Transat or Saunder. The choice of the electrode materials and the thickness of the electrode are controlled by filament temperature and total heating time. The size and shape of electrodes are defined by proper use of masks. A tuning fork could be made from micro-machining (e.g., wet etching, etc) of quartz wafer.

Surface acoustic wave resonator (SAW-R), surface acoustic wave delay line (SAW-DL), surface acoustic wave filter (SAW-F), surface transverse wave (STW), bulk acoustic wave (BAW), tuning fork, and acoustic plate mode (APM) all can be utilized in various sensing measurement applications. One of the primary differences between an acoustic wave sensor and a conventional sensor is that an acoustic wave can store energy mechanically. Once such a sensor is supplied with a certain amount of energy (e.g., through RF), the sensor can operate for a time without any active part (e.g., without a power supply or oscillator). This feature makes it possible to implement an acoustic wave device in an RF powered passive and wireless sensing application.

One area where acoustic wave devices may find particular usefulness is in the field of rotation rate or gyro sensing. A gyro sensor, which is a type of sensor utilized for detecting the angular velocity of rotation, has been hitherto used, for example, for inertial navigation systems of aircraft and shipping. Recently, the gyro sensor has been adapted for use in vehicle-carried navigation systems and for attitude control systems of automatically guided robot vehicles. Further, the gyro sensor can also be utilized, for example, for picture blurring-preventive systems of VTR cameras. In such circumstances, a compact type gyro sensor is required, which is appropriately used in various fields as described above.

One of the problems with conventional gyro sensors is that such devices are typically implemented in the context of wired systems. When involved with a rotating or moving part, however, a wire connection presents many difficulties, the least of which is the ability to ensure that the information wireless transmitted is accurate. To date, wireless gyro sensors have not been successfully implemented. It is believed that the use of a tuning fork or a surface acoustic wave sensor in the context of a rotation rate or gyro sensor can overcome the aforementioned problems.

### BRIEF SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the present invention to provide for an improved sensing device.

It is another aspect of the present invention to provide for an improved acoustic wave sensing device

It is yet another aspect of the present invention to provide for a wireless and passive acoustic wave sensor for the detection of rotation rate or gyro data. The aforementioned aspects and other objectives and advantages can now be achieved as described herein. A rotation rate sensing apparatus is disclosed, which is configured from an acoustic wave device comprising either an electrode (i.e., tuning fork) or a plurality of interdigital transducers (i.e., surface acoustic wave) configured upon an elastic substrate. In the surface acoustic wave design, the plurality of interdigital transducers includes a first interdigital transducer, a second interdigital transducer and a third interdigital transducer.

A generator(s) can be formed from the first and third interdigital transducers, wherein the generator generates a standing wave subject to a Coriolis force by adding two progressive waves at each of the first and third interdigital transducers. Additionally, a sensor can be formed from the second interdigital transducer, wherein the elastic substrate is rotatable in a first direction in order to excite an electric field at the sensor in order to detect an amplitude of the electric field, wherein the amplitude, which is proportional to the magnitude of the Coriolis force, provides an indication of angular rate data thereof. The first, second and third interdigital transducers comprise resonators, and the second interdigital transducer is located centrally on the elastic substrate between the first and third interdigital transducers. In general, the “first direction” described above comprises a right direction relative to the elastic substrate. The elastic substrate is preferably formed from a piezoelectric material.

In the case of tuning fork, a piezoelectric gyroscope makes use of two vibration modes of a vibrating piezoelectric body. In these two modes, material particles move in perpendicular directions respectively. When a piezoelectric gyroscope is excited into vibration in one of the two modes (e.g., the primary mode) by an applied alternating voltage (or through RF) and attached to a rotating body, the Coriolis force excites the other mode (e.g., the secondary mode) through which the angular rate of the rotating body can be detected electrically.

The natural frequencies of the two modes generally should be very close to one another, and also very close to the driving frequency so that the gyroscope functions at resonant conditions with maximum sensitivity. Examples include flexural vibrations in two perpendicular directions of beams and tuning forks, thickness-shear vibrations in two perpendicular directions of a plate's piezoelectric material, and radial and torsional vibrations of circular cylindrical shells thereof. Degenerate modes of circular disks, shells, and rings can also be used to construct a gyroscope. Structurally, a piezoelectric gyroscope can be configured either from piezoelectric materials alone, or piezoelectric films bonded to elastic structures.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1 illustrates a perspective view of an interdigital surface wave device, which can be implemented in accordance with one embodiment;

FIG. 2 illustrates a cross-sectional view along line A-A of the interdigital surface wave device depicted in FIG. 1, in accordance with one embodiment;

FIG. 3 illustrates a perspective view of an interdigital surface wave device, which can be implemented in accordance with another embodiment;

FIG. 4 illustrates a cross-sectional view along line A-A of the interdigital surface wave device depicted in FIG. 3, in accordance with another embodiment;

FIG. 5 illustrates a graph depicting the Corliolis force acting on particle vibrations in a standing wave;

FIG. 6 illustrates a top view of a passive and wireless SAW rotation rate sensor that can be implemented in accordance with a preferred embodiment; and

FIG. 7 illustrates a wireless and passive SAW rotation rate sensing system that can be implemented in accordance with a preferred embodiment;

FIG. 8 illustrates a side view of a passive and wireless tuning fork rotation rate sensor that can be adapted for use in accordance with a preferred embodiment; and

FIG. 9 illustrates basic mode shapes of an “H” shape tuning fork rotation rate sensing device that can be implemented in accordance with varying embodiments.

### DETAILED DESCRIPTION

The particular values and configurations discussed in these non-limiting examples can be varied and are cited merely to illustrate at least one embodiment and are not intended to limit the scope thereof.

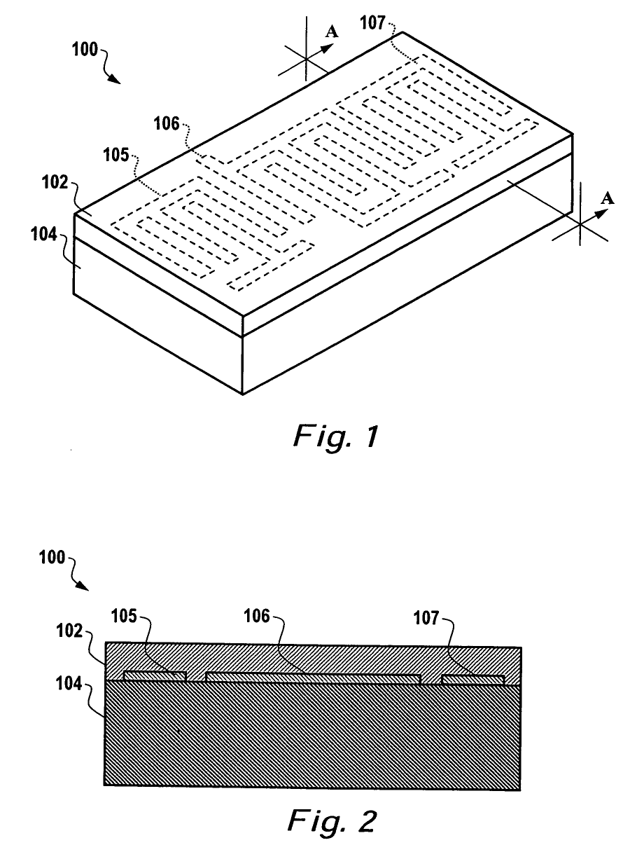

FIG. 1 illustrates a perspective view of an acoustic wave device 100, which can be implemented in accordance with one embodiment. Acoustic wave device 100 generally includes one or more interdigital transducers (IDT) 105, 106, 107, which can be formed on a substrate 104, which may be formed from an elastic substrate material. Substrate 104 is preferably formed from a piezoelectric material. The acoustic wave device 100 can be implemented in the context of a sensor chip. Interdigital transducers 105, 106, 107 can be configured in the form of electrodes or resonators, depending upon design considerations.

Note that the acoustic wave device 100 represents only one type of acoustic wave device that can be adapted for use with the embodiments disclosed herein. It can be appreciated that a variety of other types (e.g., SH-SAW, BAW, APM, SH-APM, FPW, SH-SAW-DL, SH-SAW-R, etc.) can be utilized in accordance with the embodiments described herein. Additionally, acoustic wave device 100 can be implemented in a variety of shapes and sizes.

FIG. 2 illustrates a cross-sectional view along line A-A of the acoustic wave device 100 depicted in FIG. 1, in accordance with one embodiment of the present invention. Piezoelectric substrate 104 can be formed from a variety of substrate materials, such as, for example, quartz, lithium niobate (LiNbO₃), lithium tantalite (LiTaO₃), Li₂B₄O₇, GaPO₄, langasite (La₃Ga₅SiO₁₄), ZnO, and/or epitaxially grown nitrides such as Al, Ga or Ln, to name a few. Interdigital transducers 105, 106, 107 can be formed from materials, which are generally divided into three groups. First, interdigital transducers 105, 106, 107 can be formed from a metal group material (e.g., Al, Pt, Au, Rh, Ir Cu, Ti, W, Cr, or Ni). Second, interdigital transducers 105, 106, 107 can be formed from alloys such as NiCr or CuAl. Third, interdigital transducers 105, 106, 107 can be formed from metal-nonmetal compounds (e.g., ceramic electrodes based on TiN, CoSi₂, or WC).

The coating 102 need not cover the entire planar surface of the piezoelectric substrate 104, but can cover only a portion thereof, depending upon design constraints. Coating 102 can function as a guiding layer. Selective coating 102 can cover interdigital transducers 105, 106, 107 and the entire planar surface of piezoelectric substrate 104. Because acoustic wave device 100 functions as a multiple mode sensing device, excited multiple modes thereof generally occupy the same volume of piezoelectric material. Multiple modes excitation allows separations of temperature change effects from pressure change effects. The multi-mode response can be represented by multiple mode equations, which can be solved to separate the response due to the temperature and pressure.

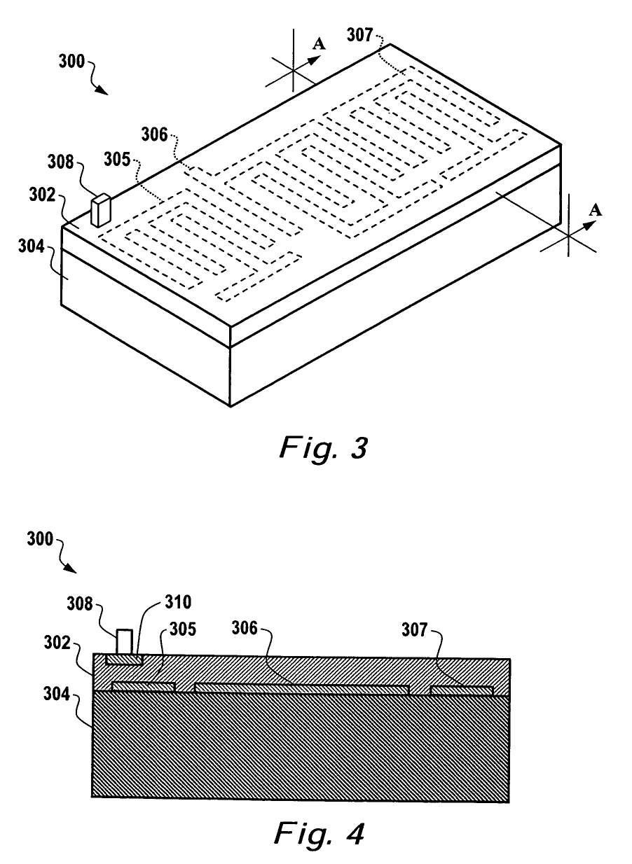

FIG. 3 illustrates a perspective view of an acoustic wave device 300, which can be implemented in accordance with an embodiment. The configuration depicted in FIGS. 3-4 is similar to that illustrated in FIGS. 1-2, with the addition of an antenna 308, which is connected to and disposed above a wireless excitation component 310 (i.e., shown in FIG. 4). Acoustic wave device 300 generally includes interdigital transducers 305, 306, 307 formed on a piezoelectric substrate 304.

Acoustic wave device 300 can therefore function as an interdigital surface wave device, and one, in particular, which utilizing surface-skimming bulk wave techniques. Interdigital transducers 305, 306, 307 can be configured in the form of an electrode. A coating 302 can be selected such that a particular species to be measured is absorbed by the coating 302, thereby altering the acoustic properties of the acoustic wave device 300. Various selective coatings can be utilized to implement coating 302.

A change in acoustic properties can be detected and utilized to identify or detect the substance or species absorbed and/or adsorbed by the coating 302. Thus, coating 302 can be excited via wireless means to implement a surface acoustical model. Thus, antenna 308 and wireless excitation component 310 can be utilized to excite multiple modes, thereby allowing separation of temperature change effects from pressure change effects. Such an excitation can produce a variety of other modes of acoustic wave device 300.

FIG. 4 illustrates a cross-sectional view along line A-A of the acoustic wave device 300 depicted in FIG. 3, in accordance with one embodiment of the present invention. Thus, antenna 308 is shown in FIG. 4 disposed above coating 302 and connected to wireless excitation component 310, which can be formed within an area of coating 302. Similar to the configuration of FIG. 2, Piezoelectric substrate 304 can be formed from a variety of substrate materials, such as, for example, quartz, lithium niobate (LiNbO₃), lithium tantalite (LiTaO₃), Li₂B₄O₇, GaPO₄, langasite (La₃Ga₅SiO₁₄), ZnO, and/or epitaxially grown nitrides such as Al, Ga or Ln, to name a few.

Interdigital transducers 305, 306, 307 can be formed from materials, which are generally divided into three groups. First, interdigital transducer 106 can be formed from a metal group material (e.g., Al, Pt, Au, Rh, Ir Cu, Ti, W, Cr, or Ni). Second, interdigital transducers 305, 306, 307 can be formed from alloys such as NiCr or CuAl. Third, interdigital transducers 305, 306, 307 can be formed from metal-nonmetal compounds (e.g., ceramic electrodes based on TiN, CoSi₂, or WC). Thus, the electrode formed from interdigital transducer can comprise a material formed from at least one of the following types of material groups: metals, alloys, or metal-nonmetal compounds.

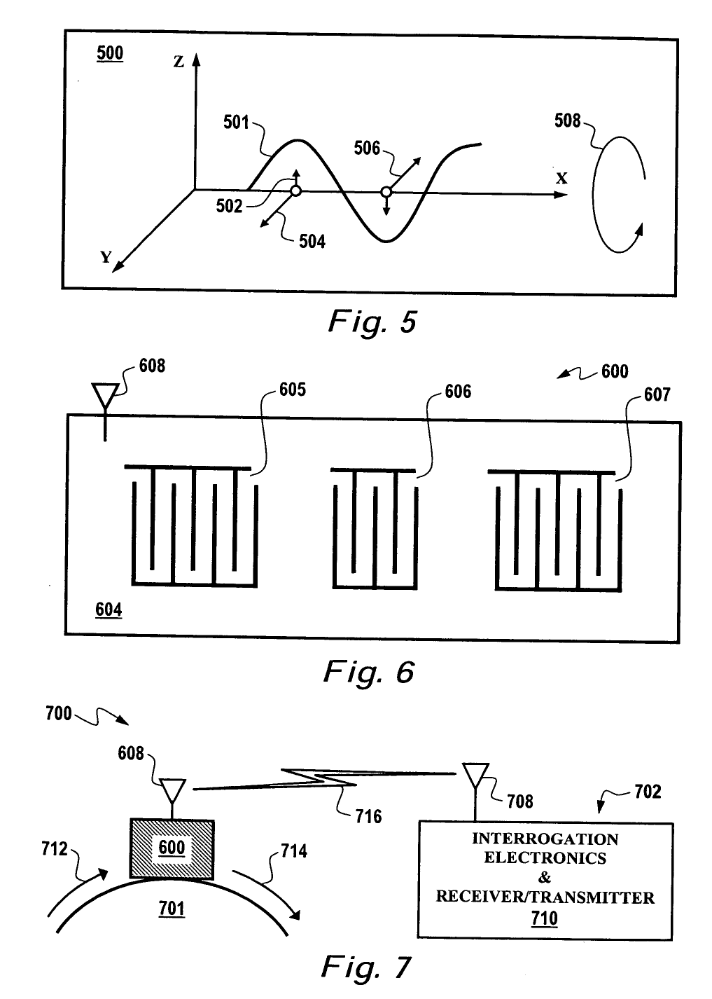

FIG. 5 illustrates a graph 500 depicting the Coriolis force acting on particle vibrations in a standing wave 501 in accordance with a preferred embodiment. In graph 500, the rotating direction is indicated generally by curved arrow 508 relative to the x-y-z axes. The Coriolis force is represented in graph 500 by arrow 500, while the vibration velocity 502 is indicated by the value T. Note that as utilized herein, the term “Coriolis force” generally refers to the Coriolis force or Coriolis effect, which is the inertial force associated with a change in the tangential component of a particle's velocity. The Coriolis force generally acts on moving objects when observed in a frame of reference which is itself rotating. Because of the rotation of the observer, a freely moving object does not appear to move steadily in a straight line as usual, but rather as if, besides an outward centrifugal force, a “Coriolis force” acts on it, perpendicular to its motion, with a strength proportional to its mass, its velocity and the rate of rotation of the frame of reference.

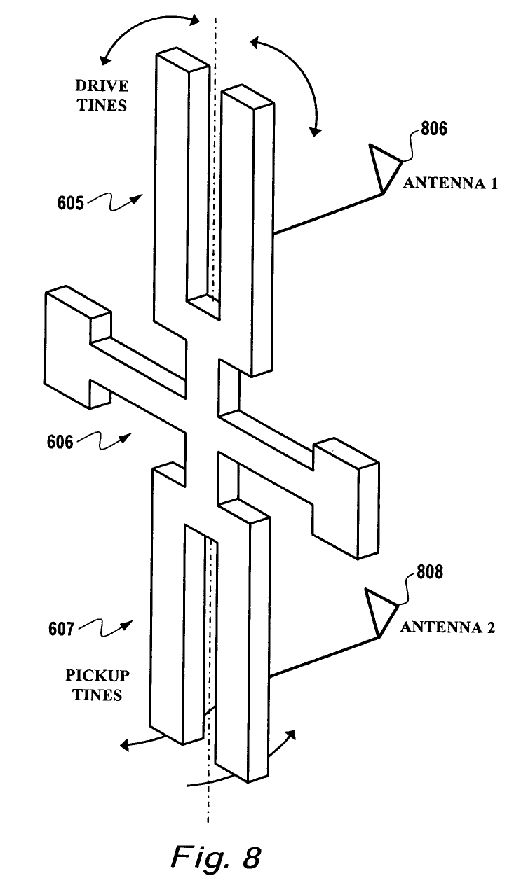

FIG. 6 illustrates a top view of a passive and wireless acoustic wave (e.g., SAW and/or tuning fork) rotation rate sensor 600 that can be implemented in accordance with a preferred embodiment. Sensor 600 generally functions as a rotation rate sensing apparatus in the form of a surface acoustic wave device that includes a plurality of interdigital transducers 605, 606, and 607 configured upon an elastic substrate 604, which may be formed from a piezoelectric material. Note that substrate 604 is analogous to substrates 104, 103 depicted in FIGS. 1-4 herein. Interdigital transducer 605 generally functions as a first interdigital transducer, while interdigital transducer 606 comprises a second interdigital transducer and interdigital transducer 607 comprises a third interdigital transducer in the context of three IDT system. Sensor 600 generally functions as a rotation rate sensing apparatus in the form of a tuning fork device as illustrated in further detail herein with respect to FIG. 8

First and third interdigital transducers 605 and 607 respectively form generator resonators that can generate a standing wave (e.g., see wave 501 in FIG. 5) subject to the Coriolis force (e.g., see arrow 504 in FIG. 5) by adding two progressive waves at each of the first and third respective interdigital transducers 605, 607. The second interdigital transducer 606 forms a sensor that is also configured upon the elastic substrate 604 in order to excite an electric field at the second interdigital transducer or sensor 606 in order to detect the amplitude of the electric field. The amplitude thereof is proportional to the magnitude of the Coriolis force and provides an indication of angular rate data thereof. Additionally, an antenna 608 can be formed on the substrate 604 for the transmission of angular or rotation rate data.

The design of the passive and wireless SAW rotation rate sensor 600 is such that three SAW resonators 605, 606, 607 can be implemented as indicated in FIG. 6. The two SAW resonators or interdigital transducers 605, 607 function as a generator, and SAW resonator or interdigital transducer 606 functions as a sensor or sensor resonator. The standing wave 501 indicated in FIG. 5 can be generated utilizing two progressive waves generated at each generator resonator 605, 607. The sensor resonator 606 is located at the center of the two generator resonators 605, 607. When the substrate 604 is rotated in the right direction, an electric field is excited at the sensor resonator 606. The amplitude of this electric field is proportional to the magnitude of the Coriolis force depicted at arrow 504 in graph 500 of FIG. 5. The Coriolis force thus excites the electric field between electrodes. Note that the interdigital transducers 605, 606, 607 can be implemented in the context of one or more of the following: a filter, a resonator a plurality of delay lines.

FIG. 7 illustrates a wireless and passive SAW rotation rate sensing system 700 that can be implemented in accordance with a preferred embodiment. Note that in FIGS. 6-7, identical or similar parts are indicated by identical reference numerals. System 700 generally includes the passive and wireless SAW rotation rate sensor 600 depicted in FIG. 6. The passive and wireless SAW rotation rate sensor 600 can be located or associated with a rotating object 701. Rotation of the object 701 is indicated by arrows 712, 714. Wireless data can be transmitted from and to the passive and wireless SAW rotation rate sensor 600 via antenna 608 by an interrogation electronics (ID) and transmitter/receiver unit 710, which is associated with an antenna 708.

FIG. 8 illustrates a wireless and passive tuning fork rotation rate sensing device 800 that can be implemented in accordance with the passive and wireless acoustic wave rotation rate sensor 600 depicted in FIG. 6-7. The tuning fork rotation rate sensing device 800 can be adapted for use with the passive and wireless tuning fork rotation rate sensor 600 depicted in FIGS. 6-7. Note that in FIGS. 6-8, identical or similar parts are indicated by identical reference numerals. Note that other configurations can also be adapted for use in accordance with varying embodiments.

As indicated earlier, the passive and wireless acoustic wave rotation rate sensor 600 can be located on or associated with the rotating object 701. Rotation of the object 701 is indicated by arrows 712, 714. Wireless data can be transmitted from and to the passive and wireless tuning fork rotation rate device 600 via antennas 806 and 808 by an interrogation electronics (ID) and transmitter/receiver unit 710, which is associated with an antenna 708. Note that antennas 806, 800 indicated in FIG. 8 can be implemented in place or in association with antenna 608 depicted in FIG. 7. In general, the wireless and passive tuning fork rotating rate sensing device 800 can be configured upon substrate 604.

Primary tuning fork electrode, for example, can be shaped in the context of “drive tines” or a drive electrode, as indicated in FIG. 8. Similarly, secondary tuning fork electrode can be shaped in the context of “pickup tines” or a pickup electrode, as also indicated in FIG. 8. The first antenna 806 can be associated with the drive electrode 605, while the second antenna 808 can be associated with the pickup electrode 607.

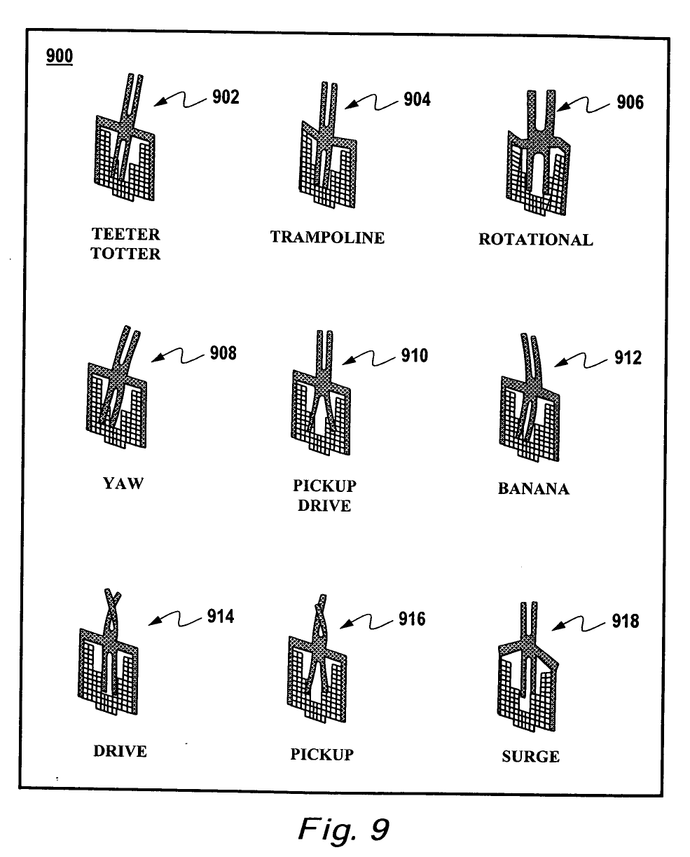

FIG. 9 illustrates basic mode shapes 900 of an “H” shape tuning fork rotation rate sensing device that can be implemented in accordance with varying embodiments. The shapes 900 are generally divided into a number of varying shapes 902-918 as indicated in FIG. 9. By utilizing the H-Shaped tuning fork configurations depicted in FIG. 9, and adapting such configurations to the sensor depicted in FIG. 6-8, a sensor can be formed that includes an elastic substrate rotatable in a first direction in order to excite an electric field at the sensor in order to detect an amplitude of the electric field, wherein the amplitude, which is proportional to the magnitude of the Coriolis force, provides an indication of angular rate data thereof. In the vibration beams configuration, drive beam(s) and pickup beam(s) can be utilized. The vibration beams are excited through RF signal and Coriolis force will excite the pickup beam(s) to get the rotation rate data.

The H-shaped tuning fork configurations depicted in FIG. 9 represent merely one type of angular sensing configuration that can be adapted for use in accordance with one or more embodiments. Other configurations are possible. An example of one type of configuration that can be adapted for use in accordance with one particular embodiment is disclosed in non-limiting U.S. Pat. No. 6,151,965, entitled “Structure of Angular Rate Sensor for Minimizing Output Noise,” which issued to Takehiro Watarai on Nov. 8, 2000. U.S. Pat. No. 6,151,965 is incorporated herein by reference.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A rotation rate sensing apparatus, comprising:
a surface acoustic wave device comprising a plurality of interdigital transducers configured upon an elastic substrate, wherein said plurality of interdigital transducers includes a first interdigital transducer, a second interdigital transducer and a third interdigital transducer;
an antenna connected to said plurality of interdigital transducers, wherein said antenna receives an excitation signal for the excitation of said rotation rate sensing apparatus and for transmitting angular rate data from said rotation rate sensing apparatus;
a generator formed from said first and third interdigital transducers, wherein said generator generates a standing wave subject to a Coriolis force by adding two progressive waves at each of said first and third interdigital transducers; and
a sensor formed from said second interdigital transducer, wherein said elastic substrate is rotatable in a first direction in order to excite an electric field at said sensor in order to detect an amplitude of said electric field, wherein said amplitude, which is proportional to the magnitude of said Coriolis force, provides an indication of angular rate data thereof.

2. The apparatus of claim 1 wherein said first, second and third interdigital transducers comprise at least one of the following: a filter, a resonator, or a plurality of delay lines.

3. The apparatus of claim 1 wherein said second interdigital transducer is located centrally on said elastic substrate between said first and third interdigital transducers.

4. The apparatus of claim 1 wherein said first direction comprises a right direction relative to said elastic substrate.

5. The apparatus of claim 1 wherein said elastic substrate is formed from a piezoelectric material.

6. The apparatus of claim 1 wherein said plurality of interdigital transducers are arranged in a shape of a tuning fork, wherein said first interdigital transducer comprise a drive electrode and said third interdigital transducer comprises a pickup electrode and said second interdigital electrode comprises a tuning fork portion located centrally and perpendicular to said first interdigital transducer and said third interdigital transducer.

7. A rotation rate sensing apparatus, comprising:
a tuning fork device comprising a plurality of electrodes configured upon an elastic substrate, wherein said plurality of electrodes comprises a drive electrode and a pickup electrode, wherein said plurality of electrodes are connected to at least one antenna that receives an excitation signal for the excitation of said rotation rate sensing apparatus and for transmitting data from said rotation rate sensing apparatus, wherein flexural vibrations thereof occur in two perpendicular directions of beams thereof;
wherein said drive electrode is utilized to excite said beams into a vibration from an external RF interrogation signal provided by said excitation signal;
wherein a Coriolis force excites at least one other mode associated with said pickup electrode through which angular rate data associated with a rotating body located proximate to said rotation rate sensing apparatus;
wherein said at least one antenna comprises a first antenna connected to said pickup electrode, wherein said first antenna transmits data associated said angular rate data wirelessly to an interrogation unit; and
a second antenna for transmitting said angular rate data and receiving at least one interrogation signal wirelessly from said interrogation unit via a transmitter and receiver unit associated therewith.

8. The apparatus of claim 7 wherein said elastic substrate is formed from a piezoelectric material.

9. The apparatus of claim 7 wherein said elastic substrate comprises a thin piezoelectric film deposited on another elastic substrate associated therewith.

10. The apparatus of claim 7 wherein said flexural vibrations in two perpendicular directions of beams comprises an H-shaped tuning fork.

11. The apparatus of claim 7 wherein said flexural vibrations in two perpendicular directions of beams include thickness-shear vibrations in two perpendicular directions of plates thereof.

12. The apparatus of claim 7 wherein said flexural vibrations in two perpendicular directions of beams include radial and torsional vibrations of a circular cylindrical shell.

13. The apparatus of claim 7 wherein said flexural vibrations in two perpendicular directions of beams include degenerate modes of circular disks, shells, or rings adapted for use in forming a gyroscope comprising said.

14. A rotation rate sensing method, comprising:
providing a surface acoustic wave device comprising a plurality of interdigital transducers configured upon a elastic substrate, wherein said plurality of interdigital transducers includes a first interdigital transducer, a second interdigital transducer and a third interdigital transducer;
forming a generator from said first and third interdigital transducers, wherein said generator generates a standing wave subject to a Coriolis force by adding two progressive waves at each of said first and third interdigital transducers;
configuring a sensor from said second interdigital transducer, wherein said second interdigital transducer is located centrally on said elastic substrate between said first and third interdigital transducers and wherein said elastic substrate is rotatable in a first direction in order to excite an electric field at said sensor in order to detect an amplitude of said electric field, wherein said amplitude, which is proportional to the magnitude of said Coriolis force, provides an indication of angular rate data thereof; and
connecting said plurality of interdigital transducers to at least one antenna that receives an excitation signal for the excitation of said rotation rate sensing apparatus and for transmitting angular rate data from said rotation rate sensing apparatus, and;
providing at least one interrogation unit associated with a transmitter/receiver unit that receives said angular rate data from said at least one antenna and transmits at least one interrogation signal wirelessly from said interrogation electronics unit via said transmitter/receiver to said at least one antenna.

15. The method of claim 14 wherein said first, second and third interdigital transducers comprise at least one of the following: a resonator, a filter or a plurality of delay lines.

16. The method of claim 14 wherein said second interdigital transducer is located centrally on said elastic substrate between said first and third interdigital transducers.

17. The method of claim 14 wherein said first direction comprises a right direction relative to said elastic substrate.

18. The method of claim 14 wherein said elastic substrate is formed from a piezoelectric material.

19. The method of claim 18 wherein said plurality of interdigital transducers are arranged in a shape of a tuning fork, wherein said first interdigital transducer comprise a drive electrode and said third interdigital transducer comprises a pickup electrode and said second interdigital electrode comprises a tuning fork portion located centrally and perpendicular to said first interdigital transducer and said third interdigital transducer.
